(19) United States
(12) Patent Application Publication
(10) Pub. No.: US 2025/0369117 A1
(43) Pub. Date: Dec. 4, 2025

(54) SEMICONDUCTOR MANUFACTURING MULTI-ZONE SHOWERHEAD

(71) Applicant: Applied Materials, Inc., Santa Clara, CA (US)

(72) Inventors: Janardhan Devrajan, Santa Clara, CA (US); Abdul Akbar Kuppakkattu, Bengaluru (IN); Rakesh Ramadas, San Jose, CA (US); Muhannad Mustafa, Milpitas, CA (US); Sai Bharadwaj Vishnubhotla, Santa Clara, CA (US); Abinash Tripathy, Bengaluru (IN)

(73) Assignee: Applied Materials, Inc., Santa Clara, CA (US)

(21) Appl. No.: 18/899,881

(22) Filed: Sep. 27, 2024

(30) Foreign Application Priority Data
May 31, 2024 (IN) 202441042398

(51) Int. Cl. C23C 16/455

(52) U.S. Cl. CPC C23C 16/45565; C23C 16/45559

(57) ABSTRACT

Gas distribution assemblies for semiconductor manufacturing processing chambers that improve flow uniformity are described. The gas distribution assemblies comprise a backing plate, a showerhead and a diffuser plate between the backing plate and the showerhead. The diffuser plate has a center opening and at least one zone opening aligned with inlets in the backing plate and recesses in the showerhead.

### CROSS-REFERENCE TO RELATED APPLICATIONS

This application claims priority to India Provisional Application No. 202441042398, filed May 31, 2024, the entire disclosure of which is hereby incorporated by reference herein.

### TECHNICAL FIELD

Embodiments of the disclosure generally relate to gas distribution assemblies for semiconductor manufacturing processing chambers. In particular, embodiments of the disclosure relate gas distribution assemblies for semiconductor manufacturing with a diffuser plate for multi-zone gas flow.

### BACKGROUND

The electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of devices continue to shrink, tolerances for individual layer non-uniformity decreases. Existing vapor deposition chambers used for chemical vapor deposition (CVD) and atomic layer deposition (ALD) incorporate a funnel-shaped lid and a showerhead with ports that introduce chemical precursors into a process area surrounded by an open liner. The chemical precursors flow from a showerhead across the surface of the substrate.

Currently, a showerhead typically has a single or multiple plenums that control the flow of gas across the wafer. Some showerheads have multiple channels where different precursors are flowed separately from each other. However, the gas flow across the substrate surface can be non-uniform. In a mass-transfer controlled process regime, the distribution of the precursors has a strong role to play in determining the uniformity of films deposited by atomic layer deposition (ALD).

Therefore, there is an ongoing need in the art for apparatus and methods to improve gas flow uniformity to improve deposition uniformity.

### SUMMARY

One or more embodiments of the disclosure are directed to gas distribution assemblies for semiconductor manufacturing processing chambers comprising: a backing plate; a showerhead and a diffuser plate. The backing plate has a center inlet and at least one zone inlet spaced a distance from the center inlet. The showerhead has an inner portion and an outer portion. The inner portion has a front surface and a back surface with a center recess formed in the back surface. At least one annular zone recess is spaced from the center recess by an annular wall formed in the back surface. The center recess is aligned with the center inlet in the backing plate and each annular zone recess is aligned with a zone inlet in the backing plate. The diffuser plate is between the backing plate and the showerhead. The diffuser plate has a back surface and a front surface defining a thickness of the diffuser plate. A center opening extends through the thickness of the diffuser plate and is aligned with the center inlet of the backing plate and the center recess of the showerhead. At least one zone opening extends through the thickness of the diffuser plate and is aligned with the at least one zone inlet in the backing plate and the at least one annular zone recess of the showerhead.

Additional embodiments of the disclosure are directed to semiconductor manufacturing processing chambers including: a chamber body, a backing plate, a showerhead, a diffuser plate, a substrate support and an outer annular insert. The chamber body includes a bottom wall and at least one sidewall. The backing plate is positioned on the at least one sidewall and encloses an interior volume of the processing chamber. The backing plate includes a center inlet, a first zone inlet spaced a first inlet distance from the center inlet, a second zone inlet spaced a second inlet distance from the center inlet greater than the first inlet distance, and an outer annular opening. The showerhead has an inner portion and an outer portion. The inner portion has a front surface and a back surface with a center recess formed in the back surface. A first annular zone recess is spaced from the center recess by a first annular wall and a second annular zone is spaced from the first annular recess by a second annular wall. The center recess is aligned with the center inlet in the backing plate. The first annular zone recess is aligned with the first zone inlet and the second annular zone recess is aligned with the second zone inlet. An outer annular opening is in the outer portion and is aligned with the outer annular opening in the backing plate. The diffuser plate is between the backing plate and the showerhead. The diffuser plate has a back surface and a front surface defining a thickness of the diffuser plate. A center opening extends through the thickness of the diffuser plate and is aligned with the center inlet of the backing plate and the center recess of the showerhead. A first zone opening is spaced a first diffuser distance from the center opening, and a second zone opening is spaced a second diffuser distance from the center opening greater than the first diffuser distance. The first zone opening is aligned with the first zone inlet in the backing plate and the first annular zone recess in the showerhead. The second zone opening is aligned with the second zone inlet in the backing plate and the second annular zone recess in the showerhead. The substrate support is within the interior volume of the processing chamber. The substrate support includes a support body on a support shaft. The support body has a support surface configured to support a wafer during processing. The outer annular insert has a flange portion and a lower extension extending from a bottom surface of the flange portion. The outer annular insert is positioned so that the bottom surface of the flange portion contacts the back surface of the backing plate and the lower extension extends through the outer annular opening in the backing plate and the outer annular opening in the outer portion of the showerhead to extend a distance beyond the front surface of the showerhead. An inner face of the lower extension of the outer annular insert has a plurality of apertures in fluid communication with a plenum in the outer annular insert.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

The shading used in the Figures is for descriptive purposes only and should not be taken as referring to a particular material of construction. The cross-hatching patterns are solely chosen to help illustrate the different components and unless otherwise noted, the various materials of construction of the different components can be the same or different.

FIG. 1 illustrates a prior art embodiment of a semiconductor manufacturing processing chamber;

FIG. 2 shows a cross-sectional view of a semiconductor manufacturing process chamber according to one or more embodiment of the disclosure;

FIG. 3 shows a cross-sectional isometric view of a semiconductor manufacturing process chamber according to one or more embodiment of the disclosure;

FIG. 4 illustrates a back isometric view of a showerhead in accordance with one or more embodiments of the disclosure;

FIG. 5 illustrates a schematic cross-sectional view of the showerhead of FIG. 4 taken along line 5-5′;

FIG. 6 shows a rear isometric view of a diffuser plate fitted into a recess in the showerhead in accordance with one or more embodiments of the disclosure;

FIG. 7 illustrates a schematic view of the front surface of a backing plate according to one or more embodiments of the disclosure;

FIG. 8 illustrates a portion of a showerhead with equal depth recesses according to one or more embodiments of the disclosure;

FIG. 9 illustrates a portion of a showerhead with different depth recesses according to one or more embodiments of the disclosure; and

FIG. 10 illustrates a schematic representation of a gas manifold connected to the showerhead according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of +15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

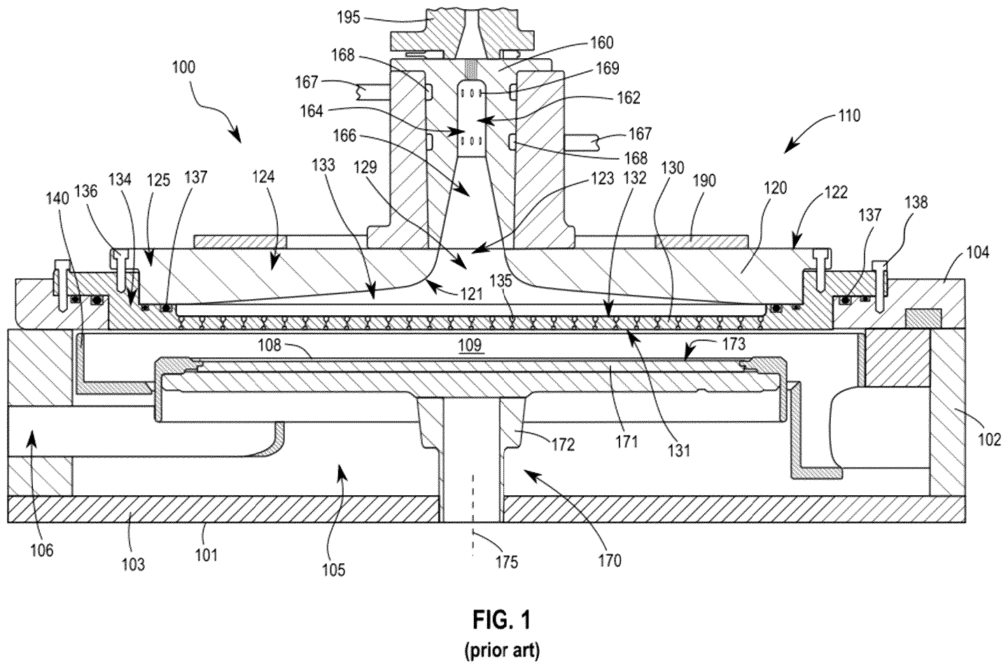

FIG. 1 illustrates a prior art embodiment of a semiconductor manufacturing processing chamber 100. The semiconductor manufacturing processing chamber 100 comprises a chamber body 101 having sidewalls 102 and a bottom 103 surrounding a interior volume 105. The sidewall 102 and bottom 103 can be integrally formed or separate component connected together by any suitable connection or fastener known to the skilled artisan. In some embodiments, the chamber body 101 includes a lid plate 104. The lid plate 104 can be permanently connected to the sidewall 102, or a separate component that is attached to the sidewall 102 by any suitable connection known to the skilled artisan.

The semiconductor manufacturing processing chambers 100 of some embodiments includes a gas distribution assembly 110. The gas distribution assembly 110 comprises a backing plate 120 and a showerhead 130.

Chamber body 101, in conjunction with the gas distribution assembly 110 encloses the interior volume 105 of the semiconductor manufacturing processing chamber 100. During processing, the interior volume 105 of the semiconductor manufacturing processing chamber 100 is typically maintained at a controlled pressure (usually a low-pressure environment) using one or more gas inlet (not shown) and one or more exhaust 106. The exhaust 106 is illustrated as part of the sidewall 102. However, the skilled artisan will recognize that the exhaust 106 can be located in any suitable. The skilled artisan will be familiar with the general construction of the chamber body 101 and the use of gas inlets and exhaust systems.

The backing plate 120 has a front surface 121 and a back surface 122 that define a thickness of the backing plate 120. The backing plate 120 has an inner portion 124 and an outer portion 125. The backing plate 120 contacts the showerhead 130 at the outer portion 125.

The backing plate 120 has an inlet opening 123 in a center thereof. The inlet opening 123 extends through the thickness of the backing plate 120 from the back surface 122 to the front surface 121. The central axis of the backing plate 120 is defined at the center of the inlet opening 123. The outer peripheral edge of the inner portion 124 of the front surface 121 is concentric with the inlet opening 123. While the backing plate 120 of some embodiments has an oblong or non-symmetrical shape, the central axis is considered to be at the center of the inlet opening 123 even if that is not the center of mass of the backing plate 120.

The front surface 121 of the backing plate 120 at the inner portion 124 has a concave shape. The concave shape of some embodiments has a linear slope from the inlet opening 123 to the outer peripheral edge of the inner portion 124 at the transition to the outer portion 125. In some embodiments, as shown in FIG. 1, the concave shape has a curved profile from the inlet opening 123 to the outer peripheral edge of the inner portion 124.

The gas distribution assembly 110 includes a showerhead 130, which may also be referred to as a “showerhead”. The showerhead 130 has a front surface 131 and a back surface 132 defining a thickness of the showerhead 130. The showerhead 130 has an inner portion 133 and an outer portion 134. The inner portion 133 of the showerhead 130 aligns with the inner portion 124 of the backing plate 120 and the outer portion 134 of the showerhead 130 aligns with the outer portion 125 of the backing plate 120. The inner portion 133 of the showerhead 130 comprises a plurality of apertures 135 extending through the thickness of the showerhead 130.

The backing plate 120 can be connected to the showerhead 130 by any suitable connection known to the skilled artisan. For example, the backing plate 120 can be welded to the showerhead 130. In some embodiments, as illustrated in FIG. 1, the backing plate 120 is connected to the showerhead 130 with a plurality of fasteners 136. In some embodiments, the showerhead 130 is connected to the lid plate 104 using a plurality of fasteners 138. Suitable fasteners include, but are not limited to, bolts, and can be used with or without O-rings 137.

When the front surface 121 of the outer portion 125 of the backing plate 120 is in contact with the outer portion 134 of the back surface 132 of the showerhead 130, a gas box plenum 129 is formed in the space between the front surface 121 of the inner portion 124 of the backing plate 120 and the inner portion 133 of the back surface 132 of the showerhead 130.

In some embodiments, the gas box plenum 129 has a coating to improve chemical compatibility. In some embodiments, the coating covers the entire front surface 121 of the backing plate 120 and the entire back surface 132 of the showerhead 130, including in the inlet opening 123 of the backing plate 120 and the plurality of apertures 135 of the showerhead 130. In some embodiments, the coating is only on the portions of the backing plate 120 and showerhead 130 that will come into contact with the process gases.

In some embodiments, the gas distribution assembly 110 further comprises a cap housing 150 connected to the back surface 122 of the backing plate 120. The cap housing 150 has a gas insert 160 with an inner channel 162 aligned with the opening 123 in the center of the backing plate 120. The inner channel 162 of some embodiments has an upper portion 164 and a lower portion 166. The upper portion 164 has a larger inner diameter than the inner diameter of the lower portion 166.

In use, one or more gases flow through inlets 167 into a plenum 168 formed between an inner surface of the cap housing 150 and an outer surface of the gas insert 160. A plurality of apertures 169 form a fluid connection between the plenum 168 and the inner channel 162.

In some embodiments, the processing chamber 100 further comprises a pumping ring 140 within the interior volume 105. In some embodiments, the pumping ring 140 is positioned on a top surface of a choke plate (not shown) which is positioned on the sidewall 102 of the chamber body 101 of the semiconductor manufacturing processing chamber 100. The pumping ring 140 has a front surface and a back surface defining a thickness of the pumping ring 140. In use, the back surface of the pumping ring 140 is positioned adjacent to or in contact with the front surface 131 of the showerhead 130. In some embodiments, in use, the front surface of the pumping ring 140 is positioned in contact with the top surface of the choke plate.

The pumping ring 140 of some embodiments comprises a plurality of openings 142 that form a fluid connection between the process gap 109 and an exhaust plenum 144. In some embodiments, the pumping ring 140 includes an outer wall 146 that forms the exhaust plenum 144.

The semiconductor manufacturing processing chamber 100 comprises a substrate support 170 within the interior volume 105. The substrate support 170 of some embodiments comprises a support body 171 positioned on a support shaft 172. The support body 171 has a support surface 173 configured to support a semiconductor wafer 108 for processing.

The support shaft 172 of some embodiments is configured to move the support body 171 closer to/further from the showerhead 130 and/or around a rotational axis 175 of the support shaft 172. During processing, the support surface 173 is spaced from the front surface 131 of the showerhead 130 to form a process gap 109. While not shown, the skilled artisan will understand that rotational and translational movement of the substrate support 170 can be driven by any suitable mechanism including, but not limited to, motors and actuators.

In some embodiments, the support body 171 includes a thermal element (not shown) configured to heat the semiconductor wafer 108 on the support surface 173. The thermal element can be any suitable heating mechanism known to the skilled artisan. For example, in some embodiments, the thermal element comprises a resistive heating element that is connected to a power supply (not shown) configured to apply power to the thermal element to heat the support body 171. In some embodiments, the support body 171 includes an electrostatic chuck (ESC) (not shown). The skilled artisan will be familiar with the construction of the ESC and the manner in which the ESC is powered and employed.

In some embodiments, as shown in FIG. 1, the support surface 173 comprises more than one component. For example, the illustrated embodiment has two components connected together by any suitable connection (e.g., brazing or welding). Use of multiple components may allow for easier assembly of the thermal elements or electrostatic chuck components which can be located between the and enclosed by the support body components.

In some embodiments, the support body 171 is surrounded by an edge ring 180. The edge ring 180 aids in centering of the semiconductor wafer 108 during processing and also helps to direct gas flows around the edge of the semiconductor wafer 108 to prevent backside deposition or other unwanted reactions on the back of the semiconductor wafer 108 or the support surface 173 of the support body 171.

Some embodiments of the gas distribution assembly 110 include a heater assembly 190 positioned adjacent the back surface 122 of the backing plate 120. The heater assembly 190 can include any suitable heater known to the skilled artisan. For example, the heater assembly 190 of some embodiments comprises a resistive heater which is connected to a power source and/or controller (not shown).

In some embodiments, the gas insert 160 includes one or more opening 165 in the top wall 161 of the gas insert 160. The one or more opening 165 can be configured to allow a flow of gas, either a reactive or inert gas, into the inner channel 162. For example, in some embodiments, a remote plasma source (RPS) (not shown) is connected to the gas insert 160 through a cooling flange 195. The cooling flange 195 is configured to allow a gas to flow through the cooling flange 195 toward the gas insert 160 while a cooling fluid is flowed through at least a portion of the cooling flange 195 to prevent elevated temperatures from the RPS from impacting the gas insert 160 or other chamber components.

Embodiments of the disclosure are directed to gas distribution assemblies that divide the showerhead into multiple, independent zones. In some embodiments, the different zones have different hole sizes and/or distribution to enable flux transfer control to the wafer. Embodiments of the disclosure can advantageously be used for single or multiple precursors. Some embodiments divide the plenum of the showerhead into independent, isolated zones to further tune the gas delivery.

Some embodiments of the disclosure advantageously enable finer control of the precursor delivery across the wafer surface. In some embodiments, precursor delivery control can be used to increase or decrease the thickness of deposition closer to the edge of the wafer when the process uniformity is controlled by the precursor flux.

In some embodiments, the showerhead is divided into multiple concentric zones or non-concentric zones. The different zones of the showerhead are isolated using o-ring seals, but these can be made into permanent, divided zones as well. The showerhead holes in each region can be made to address the needs of film deposition uniformity in that region. In addition, there are upstream, controllable valves that will allow for a certain flux of the precursor to flow into that zone. These valves can be manual valves, or pneumatic, software-controlled valves. So, the flow into a certain portion of the wafer is controlled by the hole size, distribution of showerhead holes and by the valves, which will control the amount of gas that will flow into each zone.

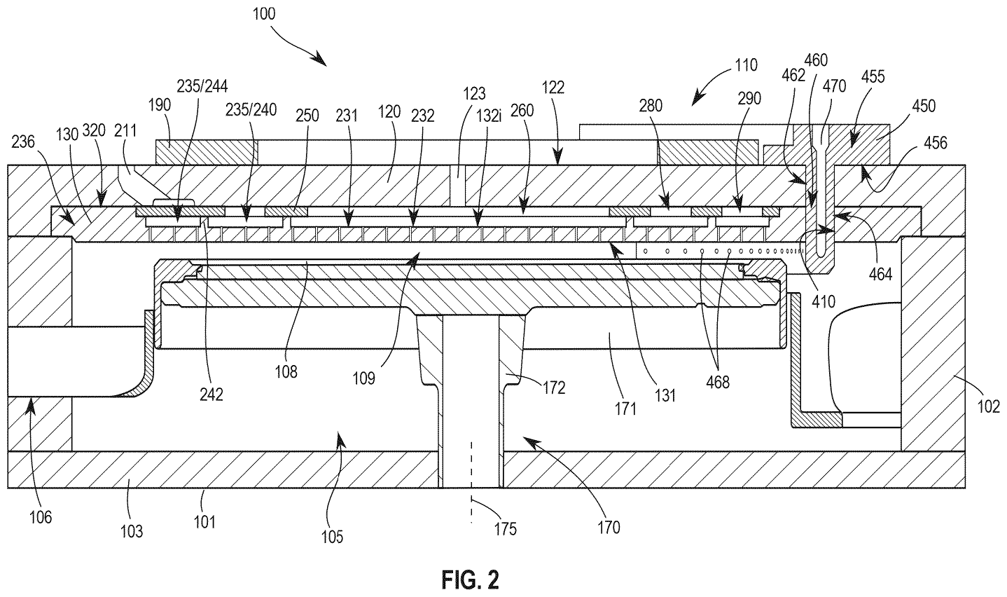

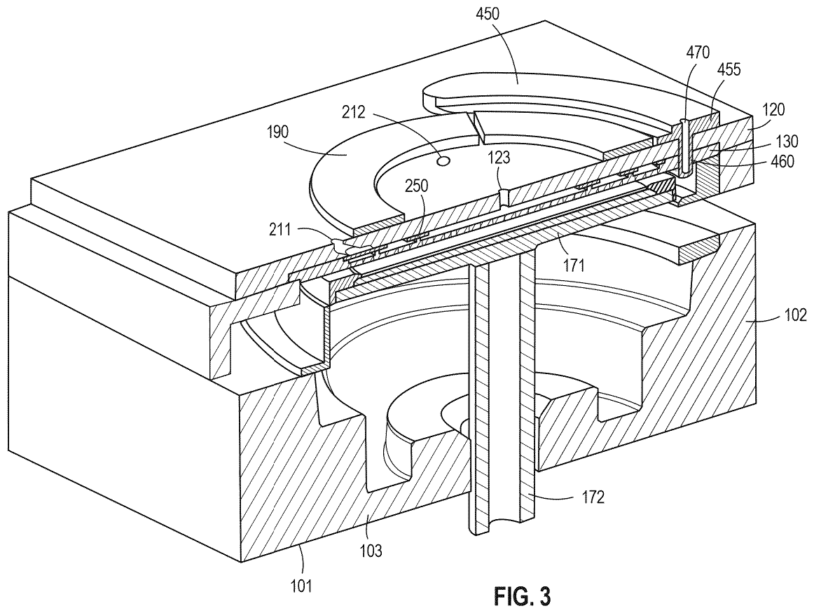

Accordingly, with reference to FIGS. 2 through 10, one or more embodiments of the disclosure are directed to gas distribution assemblies 110 for semiconductor manufacturing process chambers 100. The gas distribution assembly 110 has a backing plate 120 with a center inlet opening 123 and at least one zone inlet 211 spaced a distance from the center inlet opening 123. The cross-sectional view illustrated in FIG. 2 shows the center inlet opening 123 and one zone inlet 211. The cross-sectional isometric view of FIG. 3 shows a center inlet opening 123 with two zone inlets; zone inlet 211 and zone inlet 212. Each of the zone inlets 211, 212 are at different distances from the center inlet opening 123. Stated differently, in some embodiments, the backing plate 120 comprises a center inlet 123, a first (or intermediate) zone inlet 212 spaced a first distance from the center inlet 123, and a second (or outermost) zone inlet 211 spaced a second distance from the center inlet 123 greater than the first distance.

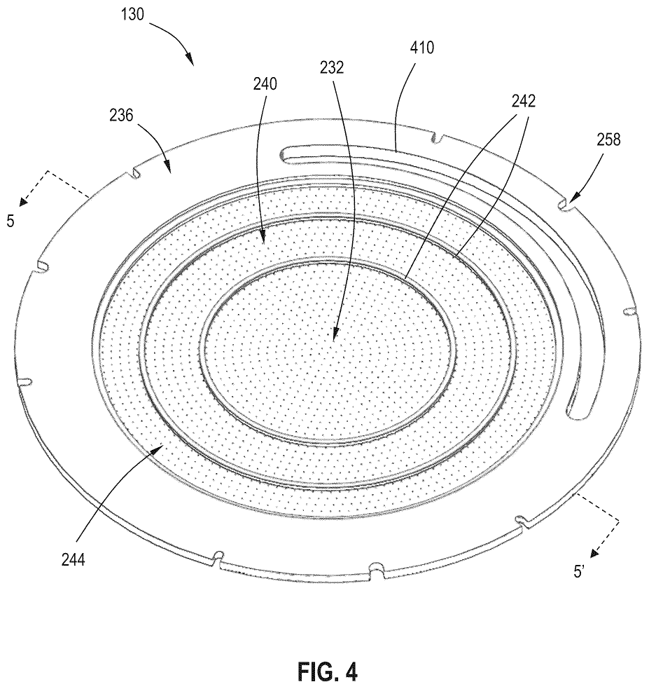

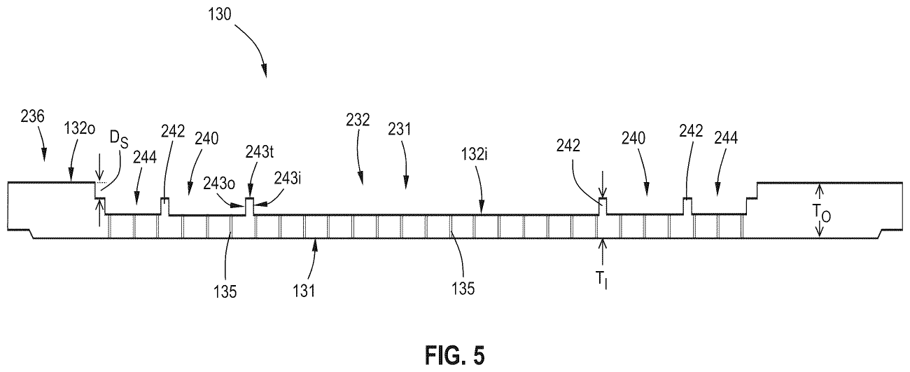

FIG. 4 illustrates a back isometric view of a showerhead 130 in accordance with one or more embodiments of the disclosure. FIG. 5 illustrates a schematic cross-sectional view of the showerhead 130 of FIG. 4 taken along line 5-5′. The showerhead 130 has an inner portion 232 and an outer portion 236. The showerhead 130 has at least one annular zone recess 235 spaced from the center recess 231 by an annular wall 242 formed in the back surface of the showerhead 130. The annular wall 242 defines the boundary between the center recess 231 and the adjacent annular zone recess 235.

In the illustrated embodiment, there are two annular walls 242 separating the inner portion 232 of the showerhead 130 into the center recess 231, at least one intermediate annular recess 240 and an outer annular recess 244. The annular wall 242 defines the separation between the center recess 231 and the at least one annular zone recess 235, and the outer annular wall 242 defines the separation between the at least one annular zone recess 235 and the outer annular recess 235. The skilled artisan will recognize that there can be more than three zones, with each zone separated from the adjacent zones by an annular wall 242.

The center recess 231 is aligned with the center inlet 123 in the backing plate 120. Each annular zone recess 235 is aligned with a zone inlet 211, 212. For example, in the illustrated embodiment, the center recess 231 is aligned with the center inlet 123 in the backing plate 120, the outermost annular zone recess 235 is aligned with the zone inlet 211 in the backing plate 120, and the intermediate zone recess 235 is aligned with the zone inlet 212 in the backing plate 120.

Referring to FIGS. 4 and 5, the inner portion 232 of the showerhead 130 is separated into three recesses formed in the back surface: a center recess 231, a first annular zone recess 240 spaced a first distance from the center recess 231 by a first annular wall 242, and a second annular zone recess 244 spaced a second distance from center recess 231 greater than the first distance, and separated from the first annular zone recess 240 by a second annular wall 242. Each annular wall 242 has a top surface 243t, an inner wall 243i and an outer wall 2430. The inner surface of the wall 243i and outer surface of the wall 2430 define a width of the annular wall 242. When there is more than one annular wall 242, each of the annular walls can have the same of different widths. In some embodiments, each of the annular walls 242 independently has a thickness in the range of 0.5 mm to 10 mm.

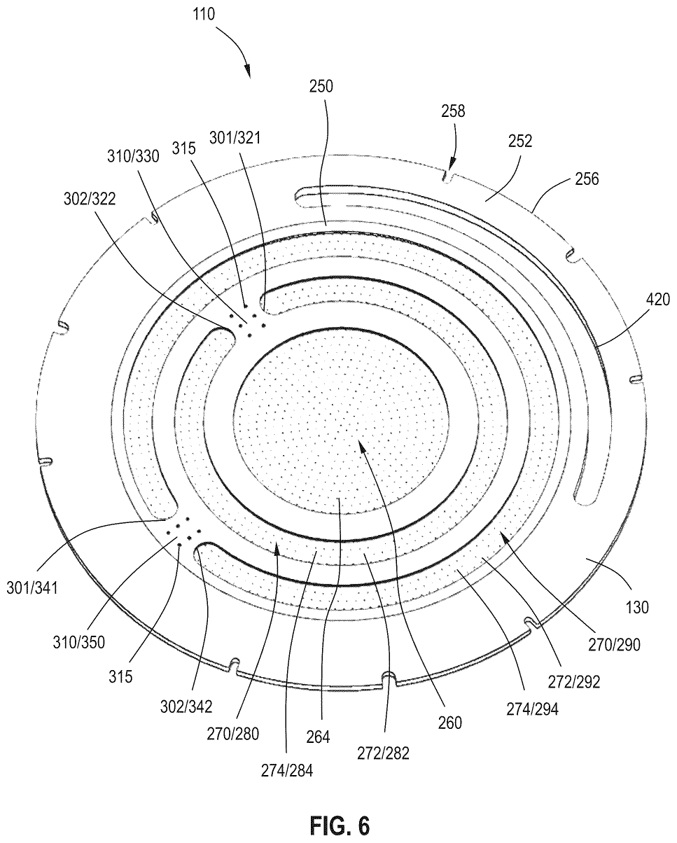

Referring back to FIGS. 2 and 3, the gas distribution assembly 110 includes a diffuser plate 250 between the backing plate 120 and the showerhead 130. FIG. 6 shows a rear isometric view of a diffuser plate 250 fitted into a recess in the showerhead 130 in accordance with one or more embodiments of the disclosure. The diffuser plate 250 has a back surface 252 and a front surface 254 defining a thickness of the diffuser plate 250. A center opening 260 extends through the thickness of the diffuser plate 250. When assembled, the center opening 260 of the diffuser plate 250 is aligned with the center inlet opening 123 of the backing plate 120 and the center recess 231 of the showerhead 130. In some embodiments, the center opening 260 extends partially through the thickness of the diffuser plate 250 to a center opening back surface 262. A plurality of openings 264 extend from the back surface 262 of the center opening 260 to the front surface 254 of the diffuser plate 250. As used in this specification and the appended claims, the term “extends through the thickness” when referring to the openings in the diffuser plate 250 means either a complete hole through the diffuser plate, as illustrated in the Figures, or a recessed section with a plurality of openings. The diffuser plate 250 of some embodiments has a thickness in the range of 100 mils to 200 mils.

The diffuser plate 250 includes at least one zone opening 270 extending through the thickness of the diffuser plate 250. The at least one zone openings 270 in the diffuser plate 250 is aligned with the at least one zone inlet 211, 212 in the backing plate 120 and the at least one annular zone recess 235 in the showerhead 130. In some embodiments, the at least one zone opening 270 is a portion of the diffuser plate 250 that is recessed to a back surface 272 and has a plurality of openings 274 extending to the front surface 254 of the diffuser plate 250.

In the illustrated embodiment, there are two zone openings 270: a first zone openings 280 and a second zone openings 290. The first zone opening 280 is a portion of the diffuser plate 250 recessed to back surface 282 with a plurality of openings 284 extending to the front surface 254 of the diffuser plate 250, and the second zone opening 290 is a portion of the diffuser plate 250 recessed to a back surface 292 with a plurality of openings 284 extending to the front surface 254 of the diffuser plate 250. When assembled, the first zone opening 280 and second zone opening 290 are aligned with the at least one zone inlet 211, 212 in the backing plate 120 and the at least one annular zone recess 235 of the showerhead 130.

Stated differently, in some embodiments, the diffuser plate 250 comprises a center opening 260, a first zone opening 280 spaced a first distance from the center opening 260, and a second zone opening 290 spaced a second distance from the center opening 260 greater than the first distance. The distance to the first zone opening 280 from the center opening 260 is measured from the outer edge of the center opening 260 to the inner edge of the first zone opening 280, and the distance to the second zone opening 290 from the center opening 260 is measured from the outer edge of the center opening 260 to the inner edge of the second zone opening 290. In some embodiments, the distance from the outer edge of the first zone opening 280 to the inner edge of the second zone opening 290 can be any suitable distance depending on the distances between the zones of the showerhead 130.

In the embodiment illustrated in FIGS. 2 and 3, the inlet opening 123 of the backing plate 120 is aligned with the center opening 260 of the diffuser plate 250 and the center recess 231 in the inner portion 232 of the showerhead 130. The zone inlet 212 of the backing plate 120 is aligned with the first zone opening 280 of the diffuser plate 250 and the first annular zone recess 240 of the showerhead 130, and the zone inlet 211 of the backing plate 120 is aligned with the second zone opening 290 of the diffuser plate 250 and the second annular zone recess 244 of the showerhead 130.

In some embodiments, the diffuser plate 250 is permanently affixed to the showerhead 130. For example, in some embodiments, the diffuser plate 250 is welded or brazed to the showerhead 130.

In some embodiments, as shown in FIG. 6, the showerhead 130 includes one or more alignment notches 258 in the outer peripheral edge. The one or more alignment notches 258 can be used to align the showerhead 130 with, for example, the backing plate 120.

In some embodiments, each of the at least one zone opening 270 in the diffuser plate 250, whether a complete opening through the diffuser plate 250, or a recessed portion with a plurality of openings, is an annular opening extending from a first end 301 to a second end 302, with a zone support region 310 between the first end 301 and the second end 302. In some embodiments, the first zone opening 280 is an annular recess to a back surface 282 with a plurality of openings 284, the annular recess extending from a first end 321 to a second end 322 with a first zone support region 330 between the first end 321 and the second end 322. The second zone opening 290 is an annular recess to a back surface 292 with a plurality of openings 294, the annular recess extending rom a first end 341 to a second end 342 with a second zone support region 350 between the first end 341 and the second end 342.

In some embodiments, each of the zone openings 270 extend around a center of the diffuser plate 250 from the first end 301 to the second end 302 in the range of 300° to 355°. As used in this manner, the center of the diffuser plate 250 is defined as the center of the center opening 260. For example, in an embodiment in which the center opening 260 and at least one zone opening 270 extend completely through the thickness of the diffuser plate 250, rather than being a recessed potion, the zone support regions help to keep the structure of the diffuser plate 250 intact. In embodiment where the center opening 260 and/or the at least one zone opening 270 are recessed portions in the diffuser plate with a plurality of openings extending to the front surface, the zone openings 270 can extend in a complete circle around the center of the diffuser plate 250 and do not have a first end 301 and second end 302 with zone support region 310 between.

In some embodiments with a zone support region 310, the zone support region 310 includes at least one aperture 315 extending through the thickness of the diffuser plate 250. The at least one aperture 315 is aligned with the zone inlet 211, 212 in the backing plate 120.

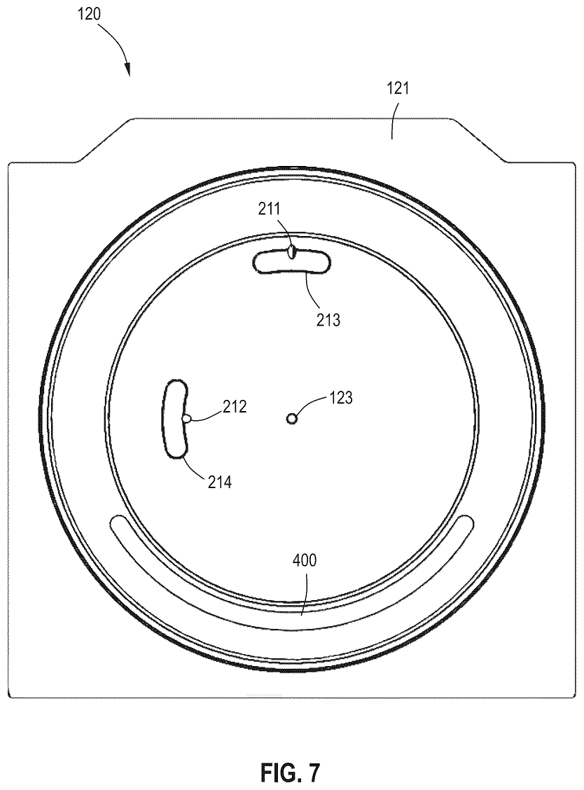

FIG. 7 illustrates a schematic view of the front surface 121 of a backing plate 120 according to one or more embodiments of the disclosure. The backing plate 120 illustrated the center inlet opening 123, the second zone inlet 211 and the first zone inlet 212. The first zone inlet 212 and second zone inlet 211 in the illustrated embodiment connect to an elongated or arcuate shaped bottom openings; first zone bottom opening 214, and second zone bottom opening 213. In some embodiments, the first zone bottom opening 214 aligns with the first zone support region 330 and overlaps with the first end 321 and second end 322 of the first zone opening 280, and the second zone bottom opening 213 aligns with the second zone support region 350 and overlaps with the first end 341 and second end 342 of the second zone opening 290.

Referring to FIGS. 4 and 7, in some embodiments, the backing plate 120 further comprises an outer annular opening 400, and the showerhead 130 comprises an outer annular opening 410 in the outer portion 236 aligned with the outer annular opening 400 in the backing plate 120. In some embodiments, the diffuser plate 250 further comprises an outer annular opening 420 that aligns with the outer annular opening 400 of the backing plate 120 and the outer annular opening 410 of the showerhead 130.

In some embodiments, as shown in FIGS. 2 and 3, the diffuser plate 250 is sized to fit within the inner portion 232 of the showerhead 130 and does not extend to the outer portion 236 of the showerhead 130. In embodiments of this sort, the diffuser plate 250 does not include an outer annular opening 420 as the backing plate 120 directly contacts or is immediately adjacent to the showerhead 130.

In some embodiments, the gas distribution assembly 110 includes an outer annular insert 450. The outer annular insert 450 has a flange portion 455 and a lower extension 460. The lower extension 460 extends from a bottom surface 456 of the flange portion 455.

The outer annular insert 450 is positioned so that the bottom surface 456 of the flange portion 455 contacts the back surface 122 of the backing plate 120 and the lower extension 460 extends through the outer annular opening 400 in the backing plate 120 and the outer annular opening 410 in the showerhead 130. The lower extension 460 of the outer annular insert 450 extends a distance beyond the front surface 131 of the showerhead 130.

The lower extension 460 has an inner face 462 and an outer face 464. The inner face 462 of some embodiments comprises a plurality of apertures 468. The plurality of apertures 468 are in fluid communication with an inner channel 470 to provide a flow of gas into the process gap 109.

Referring to FIG. 5, the showerhead 130 has a thickness T_{I} at the inner portion 232 that is less than the thickness T_{O} at the outer portion 236. The thickness T_{I} at the inner portion 232 is measured from the front surface 131 of the showerhead 130 to the top surface 243t of the annular walls 242 in the inner portion 232 of the showerhead 130. The thickness T_{O} at the outer portion 236 is measured from the front surface 131 of the showerhead to the back surface 1320 of the outer portion 236 of the showerhead 130. In some embodiments, the top surface 243t of the annular walls 242 are a depth D_{S} below the back surface 1320 of the outer portion 236 of the showerhead 130 that is about the same as the thickness of the diffuser plate 250. Stated differently, in some embodiments, the showerhead 130 has a thickness T_{I} at the inner portion 232 that is less than the thickness T_{O} at the outer portion 236 by the thickness of the diffuser plate 250.

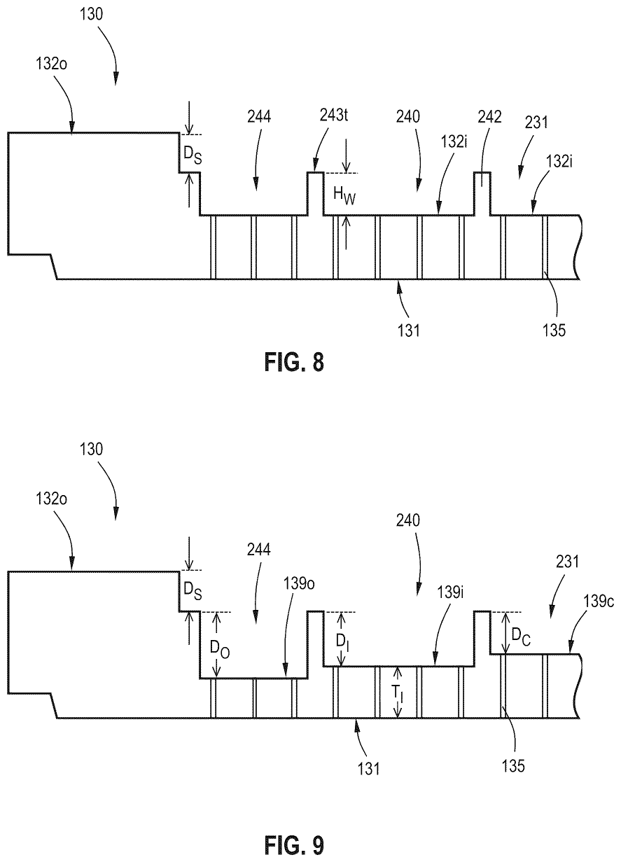

FIG. 8 illustrates a portion of a showerhead 130 with equal depth recesses according to one or more embodiments of the disclosure. In the embodiment shown, the height H_{W} of the annular walls 242, measured from the back surface 132i of the inner portion 232 to the top surface 243t of the annular wall 242, are the same, within reasonable manufacturing tolerances. Stated differently, in some embodiments, the depth of each center recess 231 and the first annular zone recess 240 and the second annular zone recess 244 are about the same.

FIG. 9 illustrates a portion of a showerhead 130 with different depth recesses according to one or more embodiments of the disclosure. In the illustrated embodiment, the depth DC of the center recess 231, measured from the back surface 139c of the center recess 231 to the top surface 243t of the annular wall 242, is less than the depth DI of the first annular zone recess 240, measured from the back surface 139i of the first annular zone recess 240 to the top surface 243t of the annular wall 242, which is less than the depth DO of the second annular zone recess 244, measured from the back surface 1390 of the second annular zone recess 244 to the top surface 243t of the annular wall 242.

The size of the individual recesses in the showerhead 130 can vary and the construction of the diffusion plate 250 will vary accordingly, as the skilled artisan will recognize. In some embodiments, the center recess 231 of the showerhead 130 has an outer diameter in the range of 100 mm to 190 mm. In some embodiments of the showerhead 130 having a center recess 231, first annular zone recess 240 and second annular zone recess 244, the first annular zone recess 240 has an inner diameter greater than the outer diameter of the center recess 231 and an outer diameter in the range of 150 mm to 275 mm. In some embodiments of the showerhead 130 having a center recess 231, first annular zone recess 240 and second annular zone recess 244, the second annular zone recess 244 has an inner diameter greater than the outer diameter of the first annular zone 240 and an outer diameter in the range of 250 mm to 350 mm.

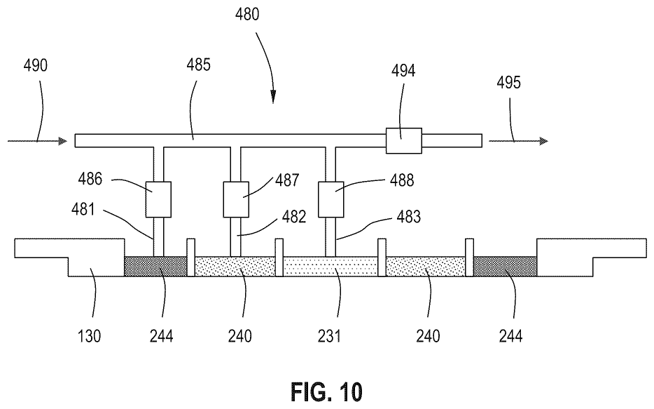

FIG. 10 illustrates a schematic representation of a gas manifold 480 connected to the showerhead 130. In the illustrated embodiment, the showerhead 130 has three concentric sections; center recess 231, first annular zone recess 240 and second annular zone recess 244. Each zone of the showerhead is connected to an individual gas line 481, 482, 483 with a separate valve 486, 487, 488. Suitable valves include, but are not limited to, needle valves. The valves 486, 487, 488 can be manually controlled or automated with software. The valves 486, 487, 488 can be adjusted to allow different amounts of precursor flowing in the inlet 490 into each of the different zones of the showerhead 130. In some embodiments, a valve 494 connects the main inlet line 485 to an exhaust system 495 (e.g., a foreline).

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A gas distribution assembly for a semiconductor manufacturing processing chamber, the gas distribution assembly comprising:
a backing plate comprising a center inlet and at least one zone inlet spaced a distance from the center inlet;
a showerhead having an inner portion and an outer portion, the inner portion having a front surface and a back surface with a center recess formed in the back surface, at least one annular zone recess spaced from the center recess by an annular wall formed in the back surface, the center recess aligned with the center inlet in the backing plate and each annular zone recess aligned with a zone inlet in the backing plate; and
a diffuser plate between the backing plate and the showerhead, the diffuser plate having a back surface and a front surface defining a thickness of the diffuser plate, a center opening extending through the thickness of the diffuser plate aligned with the center inlet of the backing plate and the center recess of the showerhead, at least one zone opening extending through the thickness of the diffuser plate aligned with the at least one zone inlet in the backing plate and the at least one annular zone recess of the showerhead.

2. The gas distribution assembly of claim 1, wherein the backing plate comprises a center inlet, a first zone inlet spaced a first distance from the center inlet, and a second zone inlet spaced a second distance from the center inlet greater than the first distance.

3. The gas distribution assembly of claim 2, wherein the diffuser plate comprises a center opening, a first zone opening spaced a first distance from the center opening, and a second zone opening spaced a second distance from the center opening greater than the first distance.

4. The gas distribution assembly of claim 3, wherein the inner portion of the showerhead comprises a center recess formed in the back surface, a first annular zone recess spaced a first distance from the center recess by a first annular wall, and a second annular zone recess spaced a second distance from center recess greater than the first distance, and separated from the first annular zone recess by a second annular wall.

5. The gas distribution assembly of claim 1, wherein the backing plate further comprises an outer annular opening, and the showerhead comprises an outer annular opening in the outer portion aligned with the outer annular opening in the backing plate.

6. The gas distribution assembly of claim 5, further comprising an outer annular insert having a flange portion and a lower extension extending from a bottom surface of the flange portion, the outer annular insert positioned so that the bottom surface of the flange portion contacts the back surface of the backing plate and the lower extension extends through the outer annular opening in the backing plate and the outer annular opening in the outer portion of the showerhead to extend a distance beyond the front surface of the showerhead.

7. The gas distribution assembly of claim 6, wherein an inner face of the lower extension of the outer annular insert comprises a plurality of apertures.

8. The gas distribution assembly of claim 1, wherein the diffuser plate is welded to the showerhead.

9. The gas distribution assembly of claim 1, wherein each zone opening of the diffuser plate is an annular opening extending in the range of 300° to 355° around the center opening from a first end to a second end, and a zone support region between the second end and first.

10. The gas distribution assembly of claim 9, wherein each of the zone support regions comprises at least one aperture extending through the diffuser plate and are aligned with a zone inlet in the backing plate.

11. The gas distribution assembly of claim 1, wherein the diffuser plate has a thickness in the range of 100 mils to 200 mils.

12. The gas distribution assembly of claim 1, wherein the at least one zone inlet in the backing plate is an arcuate shape.

13. The gas distribution assembly of claim 1, wherein the showerhead has a thickness at the inner portion that is less than a thickness at the outer portion.

14. The gas distribution assembly of claim 13, wherein the thickness at the inner portion of the showerhead is less than the thickness at the outer portion of the showerhead by the thickness of the diffuser plate.

15. The gas distribution assembly of claim 13, wherein the depth of each of the center recess and each of the annular zone recesses in the showerhead are the same.

16. The gas distribution assembly of claim 13, wherein the center recess in the showerhead has an outer diameter in the range of 100 mm to 190 mm.

17. The gas distribution assembly of claim 16, wherein the showerhead comprises a center recess, a first annular zone and a second annular zone formed in the back surface, the first annular zone recess having an inner diameter greater than the outer diameter of the center recess and an outer diameter in the range of 150 mm to 275 mm.

18. The gas distribution assembly of claim 17, wherein the second annular zone recess has an inner diameter greater than an outer diameter of the first annular zone and an outer diameter in the range of 250 mm to 350 mm.

19. The gas distribution assembly of claim 13, wherein the annular wall has a thickness in the range of 0.5 mm to 10 mm.

20. A semiconductor manufacturing processing chamber comprising:
a chamber body comprising a bottom wall and at least one sidewall;
a backing plate positioned on the at least one sidewall and enclosing an interior volume of the processing chamber, the backing plate comprising a center inlet, a first zone inlet spaced a first inlet distance from the center inlet, a second zone inlet spaced a second inlet distance from the center inlet greater than the first inlet distance, and an outer annular opening;
a showerhead having an inner portion and an outer portion, the inner portion having a front surface and a back surface with a center recess formed in the back surface, a first annular zone recess spaced from the center recess by a first annular wall and a second annular zone spaced from the first annular recess by a second annular wall, the center recess aligned with the center inlet in the backing plate, the first annular zone recess aligned with the first zone inlet and the second annular zone recess aligned with the second zone inlet, and an outer annular opening in the outer portion aligned with the outer annular opening in the backing plate
a diffuser plate between the backing plate and the showerhead, the diffuser plate having a back surface and a front surface defining a thickness of the diffuser plate, a center opening extending through the thickness of the diffuser plate aligned with the center inlet of the backing plate and the center recess of the showerhead, a first zone opening spaced a first diffuser distance from the center opening, a second zone opening spaced a second diffuser distance from the center opening greater than the first diffuser distance, the first zone opening aligned with the first zone inlet in the backing plate and the first annular zone recess in the showerhead, and the second zone opening aligned with the second zone inlet in the backing plate and the second annular zone recess in the showerhead;
a substrate support within the interior volume of the processing chamber, the substrate support comprising a support body on a support shaft, the support body having a support surface configured to support a wafer during processing; and
an outer annular insert having a flange portion and a lower extension extending from a bottom surface of the flange portion, the outer annular insert positioned so that the bottom surface of the flange portion contacts the back surface of the backing plate and the lower extension extends through the outer annular opening in the backing plate and the outer annular opening in the outer portion of the showerhead to extend a distance beyond the front surface of the showerhead, an inner face of the lower extension of the outer annular insert having a plurality of apertures in fluid communication with a plenum in the outer annular insert.
